(19) United States
(12) Patent Application Publication
(10) Pub. No.: US 2020/0027299 A1
(43) Pub. Date: Jan. 23, 2020

(54) METAL DETECTION SYSTEMS AND METHODS

(71) Applicant: Revolution Retail Systems LLC, Carrollton, TX (US)

(72) Inventors: Jorge Bermeo Hernandez, Dallas, TX (US); Eric Smith, McKinney, TX (US); James Patrick Homa, Arlington, TX (US); Robert F. Casteel, Plano, TX (US); Mark K. Levenick, Flower Mound, TX (US)

(21) Appl. No.: 16/037,265

(22) Filed: Jul. 17, 2018

(51) Int. Cl. G07D 11/00; H05K 1/18; G01V 3/10

(52) U.S. Cl. CPC G07D 11/0036; H05K 1/181; H05K 2201/1003; G07D 11/0051; G01V 3/10

(57) ABSTRACT

A metal detection device for detecting metal within notes being placed into a note recycler and handling machine includes a note guide having a note passage. The note passage has a first side and a second side. A first printed circuit board (PCB) is disposed within the first side of the note passage of the note guide. The first PCB includes a substrate and a planar metallic coil deposited on the substrate. A second PCB is disposed within the second side of the note passage of the note guide. The second PCB includes a substrate and a planar metallic coil deposited on the substrate.

### BACKGROUND OF THE INVENTION

### 1. Field of the Invention

The present invention relates to metal detection systems and methods, and more particularly to systems and methods to detect metal coins or other metal objects in note recycler and handling machines.

### 2. Description of Related Art

Conventional note recyclers or handling machines, such as those used for bill currency, sometimes experience mechanical issues due to coins and/or other foreign metallic objects entering into the machines. These issues can sometimes cause component level damage, such as gear breakage or belt breakage, or even replacement-level damage that requires the entire machine to be replaced. Conventional methods for avoiding this type of damage include visual inspection of note stacks before insertion into the machine.

The conventional techniques have been considered unsatisfactory because they are subject to human error and have been unable to prevent damage to machines caused by the presence of unwanted metal objects. Thus, there is a need for improved systems and methods to detect metal entering note recyclers and handling machines. The present invention provides improved systems and methods to detect metal entering note recyclers and or handling machines.

### SUMMARY OF THE INVENTION

A metal detection device for detecting metal within notes being placed into a note recycler and handling machine includes a note guide having a note passage. The note passage has a first side and a second side. A first printed circuit board (PCB) is disposed within the first side of the note passage of the note guide. The first PCB includes a substrate and a planar metallic coil deposited on the substrate. A second PCB is disposed within the second side of the note passage of the note guide. The second PCB includes a substrate and a planar metallic coil deposited on the substrate.

In accordance with some embodiments, the first PCB and the second PCB are parallel to one another. The metallic coil of the first PCB and the metallic coil of the second PCB can face one another. In accordance with some embodiments, at least one of the metallic coils is formed by a metallic trace arranged in a series of inwardly winding loops. The first PCB and/or the second PCB each include at least one respective connection point for electrically connecting a circuit to one or both of the metallic coils to monitor inductance of one or both of the metallic coils.

In accordance with another aspect of the disclosure, a note handling system includes a housing, and a note passage from an exterior of the housing to an interior of the housing. The note handling system includes a metal detection device operatively connected to at least one of the housing or the note passage for detecting metal foreign objects within the note passage.

The system includes a note guide within a wall of the housing. The note passage is defined through the note guide. The note guide can include an interior wall that defines the note passage. The interior wall can be positioned between the first and second PCB and the note passage.

It is contemplated that the system can include a circuit board within the housing operatively connected to the metal detection device. The system can include a note recycler within the housing to receive notes from the note passage.

The metal detection device includes a first PCB on a first side of the note passage and a second PCB spaced apart from the first PCB on a second side of the note passage. The first and second PCB can each include a substrate; and a planar metallic coil deposited on the substrate.

In accordance with another aspect, a method for detecting metal in a note handling system as described above includes receiving a note stack within the note passage of a note handling system, as described above. The method includes detecting metal in the note stack with the metal detection device, as described above.

Detecting metal in the note stack with the metal detection device can include applying a current to at least one metallic coil of the metal detection device thereby generating an electro-magnetic field. The method can include monitoring a measured inductance of the at least one metallic coil to determine if metal is detected. In some embodiments, monitoring the measured inductance includes monitoring the measured inductance continuously with a control circuit board having an inductance to digital integrated circuit.

The method can include rejecting the note stack if metal is detected. The method can include accepting the note stack into the note handling system if no metal is detected. The method can include displaying an acceptance and/or a rejection status with an indicator of the note handling system.

In accordance with another aspect, a method of retrofitting a note handling system with a metal detection system includes providing a metal detection device. The method includes operatively connecting the metal detection device to at least one of a housing or a note passage for detecting metal foreign objects within the note passage.

In some embodiments, operatively connecting the metal detection device includes securing a first PCB on a first side of the note passage. The first PCB can be similar to the first PCB described above. The method can include securing a second PCB on a second side of the note passage spaced apart from the first PCB. The second PCB can be similar to the second PCB described above. It is contemplated that the note passage can be defined through a note guide having an interior wall. Securing the first PCB on a first side of the note passage can include securing the first PCB onto an inner surface of the interior wall. The interior wall can be between the note passage and the first PCB. Securing the second PCB on a second side of the note passage can include securing the second PCB onto an inner surface of the interior wall, wherein the interior wall is between the note passage and the second PCB.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a schematic perspective view of an exemplary embodiment of a note handling system with a metal detection device constructed in accordance with the present invention, showing the note guide and note recycler;

FIG. 2 is a schematic partial cross-sectional side view of the note handling system of FIG. 1, showing the note guide, the note recycler and the printed circuit boards (PCB) of the metal detection device operatively connected to an interior wall of the note guide;

FIG. 3 a schematic perspective view of an exemplary embodiment of a note guide constructed in accordance with the present invention, showing one of the PCB operatively connected to the note guide;

FIG. 4 a schematic cross-sectional view of the note guide of FIG. 3, showing two PCBs positioned opposite from one another across the note passage;

FIG. 5 a schematic back perspective view of a portion of the system of FIG. 1, showing the note guide operatively connected to a control circuit board;

FIG. 6 is a schematic top plan view of an exemplary embodiment of one of the PCB of the metal detection device constructed in accordance with the present invention, showing the metallic coil as a rectangular shaped coil;

FIG. 7 is a flow chart schematically depicting a method of detecting metal in a note handling system in accordance with embodiments of the present invention;

FIG. 8 is a flow chart schematically depicting a method of retrofitting a note handling system with a metal detection system in accordance with embodiments of the present invention; and

FIG. 9 is a diagram schematically depicting the electrical and communication connections of the system of FIG. 1.

### DETAILED DESCRIPTION OF THE PREFERRED EMBODIMENTS

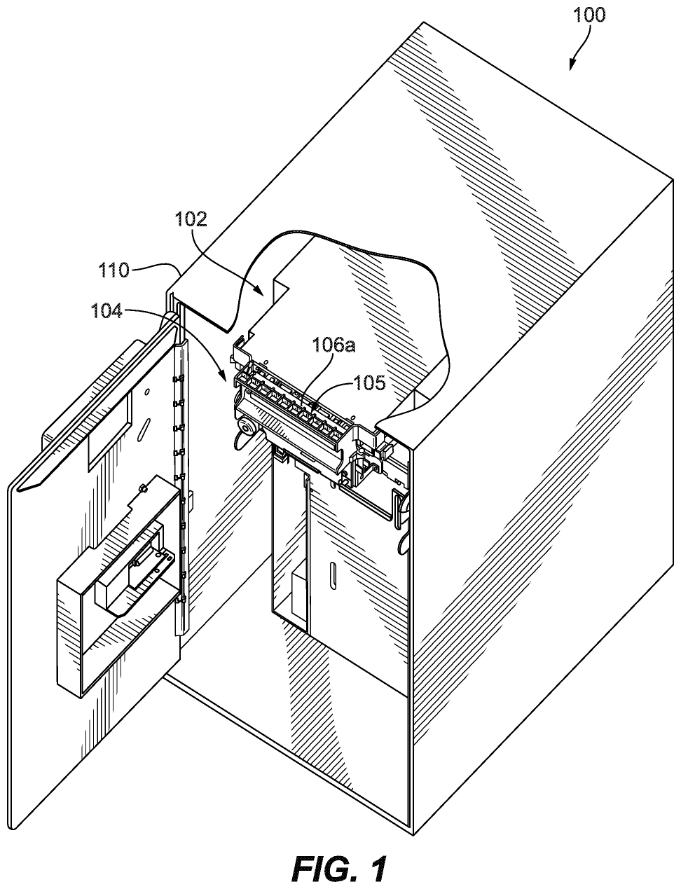

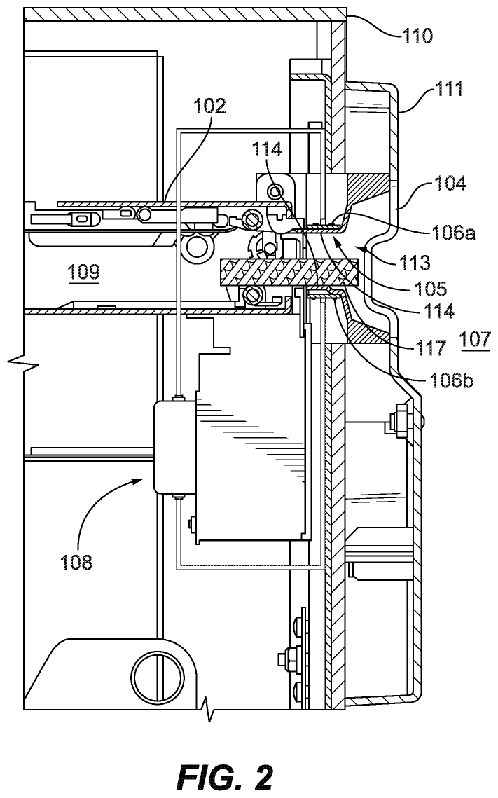

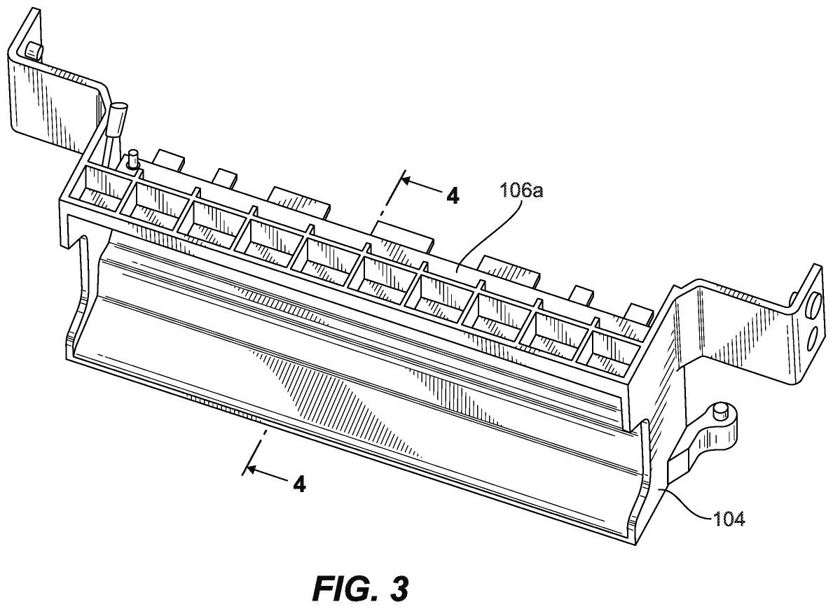

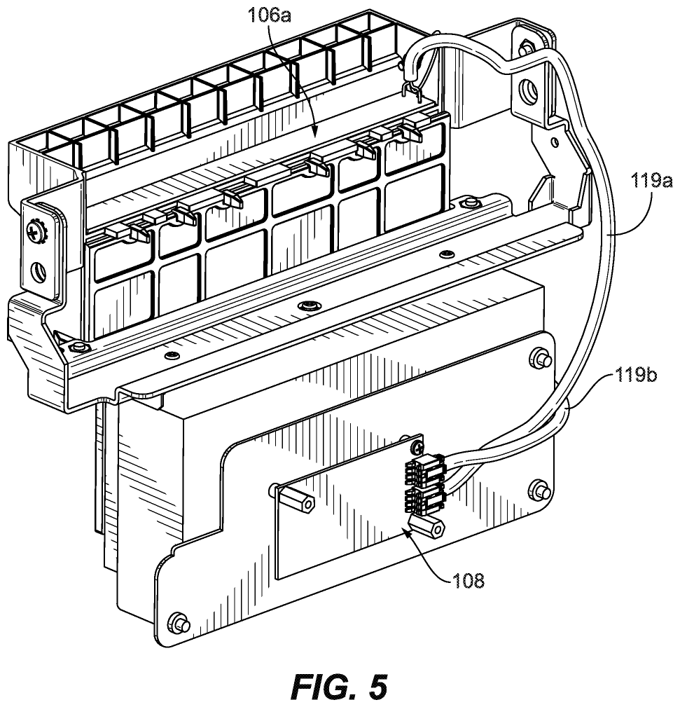

Reference will now be made to the drawings wherein like reference numerals identify similar structural features or aspects of the subject disclosure. For purposes of explanation and illustration, and not limitation, a partial view of an exemplary embodiment of a metal detection system in accordance with the disclosure is shown in FIG. 1 and is designated generally by reference character 100. Other embodiments of metal detection systems and methods in accordance with the disclosure, or aspects thereof, are provided in FIGS. 2-9 as will be described. The systems and methods described herein can be used for detecting coins and other metal objects in order to reduce or eliminate the machine failures caused by metal objects such as coins, in particular machine failures in note recycling systems.

As shown in FIGS. 1 and 2, a note handling system 100 is a machine that includes a housing 110, also referred to as a vault. Vault 110 houses and secures currency. System 100 includes a note guide 104 positioned within a wall 111 of housing 110. A note passage 113 is defined through note guide 104 from an exterior 107 of housing 110 to an interior 109 of housing 110. More specifically, note passage 113 is defined between a front edge 121 of note guide 104 to a back edge 123 of note guide 104. Note guide 104 is made from plastic, or another non-metallic material. System 100 includes a note recycler 102 within housing 110 to receive notes from note passage 113. Note handling system 100 includes a metal detection device 105 operatively connected to note passage 113 for detecting metal foreign objects within note passage 113. System 100 includes a control circuit board 108 within housing 110 operatively connected to metal detection device 105, to send/receive electrical signals indicative of inductance measured by metal detection device 105.

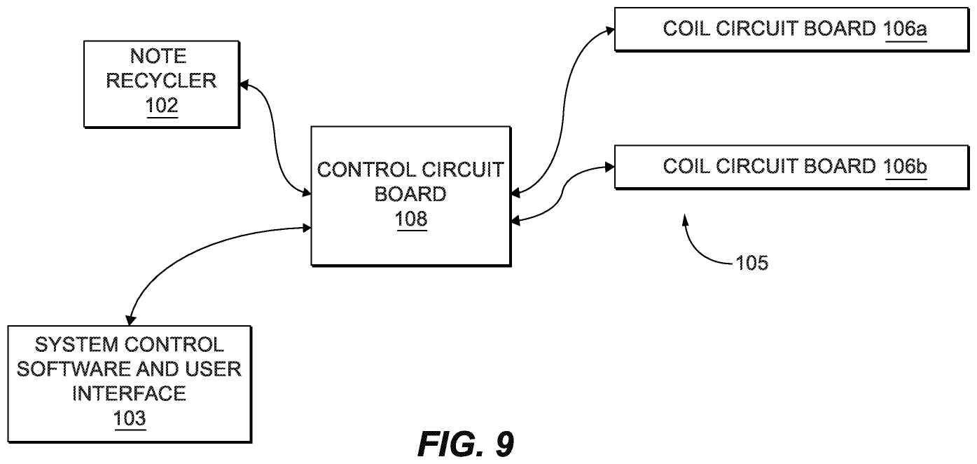

With continued reference to FIGS. 1-2 and 9, system 100 includes a note recycler 102. Note guide 104 serves to guide notes into note recycler 102 and metal detection device 105 detects metal foreign objects within note passage 113 in order to avoid metal objects, e.g. coins, paperclips, or other metallic foreign objects from being guided through into note recycler 102. As indicated schematically by arrows in FIG. 9, circuit board 108 receives electrical signals from metal detection device 105 to determine whether or not metal is within note passage 113. For example, if a note stack 117 is inserted into note guide 104 metal detection device 105 and circuit board 108 are used to determine if there is metal somewhere within note stack 117. If circuit board 108 receives a signal from metal detection device 105, and determines, from that signal, that metal is present, circuit board 108 is configured to send a command to stop note recycler 102, shown schematically by the arrows of FIG. 9. System 100 can include control software and a user interface 103, such as a display, that is in communication with control circuit board 108 and is configured and adapted to indicate to a user whether or not metal is present. It is also contemplated that the stop command from circuit board 108 can include a command to reverse rollers or other feed mechanisms in order for note stack 117 to be fed back out of note recycler 102 through note guide 104 to exterior 107 of housing 110.

As shown in FIGS. 2-4, note guide 104 includes an interior wall 114 that defines note passage 113. In some embodiments, metal detection device 105 will need to work in an area of 7.3″×0.625″×1.5″. As such, in embodiments shown herein, metal detection device 105 is made up of a first printed circuit board (PCB) 106a on a first side of note passage 113 and a second PCB 106b, spaced apart from first PCB 106a, on a second side of note passage 113. First PCB 106a and second PCB 106b are preferably parallel to one another. First PCB 106a and/or second PCB 106b are preferably 0.625 inches wide and/or 7.2 inches long. First PCB 106a is spaced apart from second PCB 106b preferably by a distance that is twice as long as a width of one of the metallic coils, e.g. about 1.25 inches.

As shown in FIG. 2, metal detection device 105 may also be in close proximity to other metal components (e.g. note recycler 102 and vault 110 and its wall 111) causing metal detection interference and electrical noise. The sizing of PCB 106a and 106b, and their respective coils, as described below, allow for system 100 to avoid false detections due to the noise interference described above, while still preserving the integrity of the detection of foreign metal objects, such as coins. Because detection device 105, e.g. first and second PCB 106a and 106b, respectively, has the dimensions described and construction described herein, metal detection device 105 is able to effectively sense metal coins and other objects under the conditions and afford enough resolution to distinguish a foreign metal object, such as a coin, from metallic components of system 100.

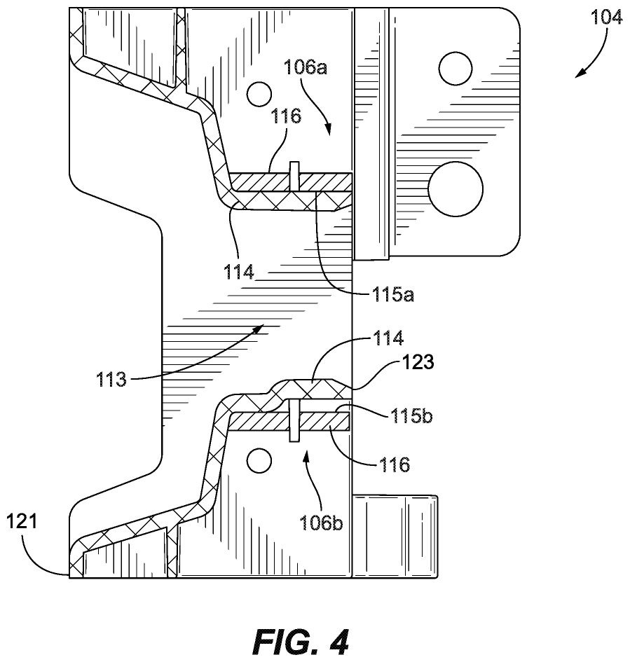

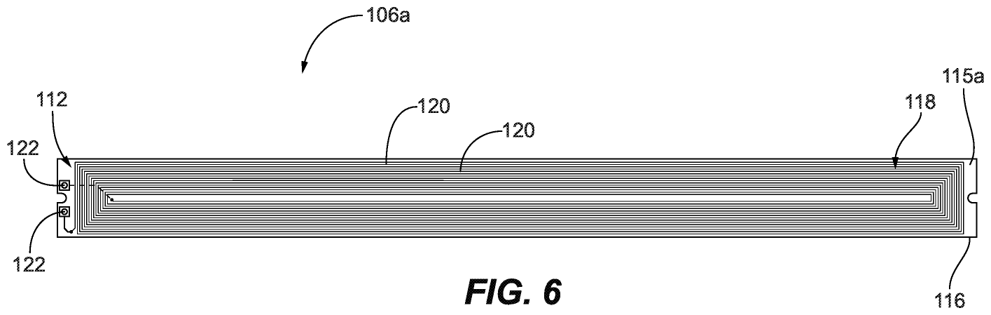

As shown in FIG. 6, first PCB 106a includes a substrate 116 and a planar metallic coil 112 deposited on an inwardly facing surface 115a of substrate 116. FIG. 6 only depicts one PCB, e.g. first PCB 106a, as second PCB 106b is substantially the same as first PCB 106a and also includes a metallic coil 112 deposited on its own inwardly facing surface 115b (shown in FIG. 4). Thus, to avoid duplicate figures, only first PCB 106a is shown. Metallic coil 112 is formed by a metallic trace 118 arranged in a series of inwardly winding loops 120 (e.g. turns). Coil 112 is an induction coil. For most induction type coils, the size of the coil determines the depth of detection. In the embodiment of FIG. 6, metallic coil 112 is a rectangular shaped coil and includes preferably approximately 15 turns 120. Metallic trace 118 is preferably approximately 0.010 inches wide. Adjacent turns 120 of metallic coil 112 are spaced apart from one another preferably by about 0.008 inches. It is contemplated that the width, due to tolerances and the like, can range from 0.006 to 0.011 inches. Similarly, the spacing of the adjacent turns 120 can range from 0.005-0.008 inches. PCB 106a includes connection points 122 for electrically connecting circuit board 108 (shown in FIGS. 1 and 2) to metallic coil 112 to monitor inductance in metallic coil 112 and for current to be provided to metallic coil 112, this produces a magnetic field within note passage 113. Each end of metallic coil 112 is electrically connected to at least one of connection points 122, e.g. shown by the dashed line between top connection point 122 (as oriented in FIG. 6) and coil 112, and the solid line between bottom connection point 122 (as oriented in FIG. 6) and coil 112. The connection between top connection point 122 and coil 112 is shown in broken lines as it would be mostly layered underneath the inwardly facing surface 115a, except for proximate to its connection to metallic coil 112 and to top connection point 122.

With reference now to FIGS. 2, 4 and 6, when positioned within note guide 104 (shown in FIGS. 1-4), metallic coil 112 of first PCB 106a faces toward interior wall 114, e.g. it faces downward as oriented in FIGS. 2 and 4. Metallic coil 112 of second PCB 106b is deposited on an inwardly facing surface 115b of substrate 116 that also faces toward interior wall 114, e.g. it faces upward as oriented in FIGS. 2 and 4. In other words, respective coils 112 of each PCB 106a and 106b face inwardly toward note passage 113 and face one another across note passage 113 and preferably through the thickness of note guide 104.

With continued reference to FIGS. 2, and 5-6, the resonating frequencies of coil 112 of first PCB 106a and coil 112 of second PCB 106b interact with one another and increase the magnetic field generated when a current is provided to each coil 112, allowing for both coils 112 to behave as one. Circuit board 108 supplies a current to coil 112 of first PCB 106a and to coil 112 of second PCB 106b by way of connections 119a and 119b, respectively. Circuit board 108 includes an inductance-to-digital integrated circuit (e.g. a chip) that monitors the inductance of at least one of coils 112. If a metal object, such as a coin, passes through the magnetic field produced by one or both of coils 112, the measured inductance of at least one of coils 112 will change. By monitoring and measuring the inductance in one or both of coils 112, certain inductance values or variations in inductance values for one or both of coils 112 can be used to determine the presence of a metal object such as a coin. Because the resonating frequencies of coils 112 interact with one another, and allow coils 112 of first and second PCBs, 106a and 106b, respectively, to act as one, the inductance-to-digital chip only needs to read one of coils 112. Even if only one coil 112 is read/monitored, the reading will be similar if a metal object or coin is placed near top coil 112, e.g. that of first PCB 106a as oriented in FIG. 2, as if it was placed near the bottom coil 112, e.g., that of second PCB 106b as oriented in FIG. 2.

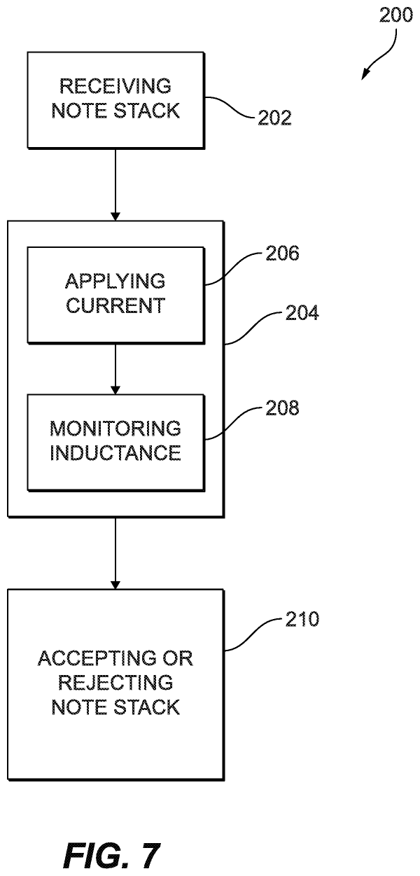

As shown in FIG. 7, a method 200 for detecting metal in a note handling system as described above includes receiving a note stack, e.g. note stack 117, within a note passage, e.g. note passage 113, of a note handling system, e.g. system 100, as indicated schematically by box 202. Method 200 includes detecting metal in the note stack with a metal detection device, e.g. metal detection device 105, as indicated schematically by box 204. Detecting metal in the note stack with the metal detection device includes applying a current to at least one metallic coil, e.g. coil 112, of the metal detection device thereby generating an electro-magnetic field, as indicated schematically by box 206.

With continued reference to FIG. 7, method 200 includes monitoring a measured inductance of the at least one metallic coil to determine if metal is detected, as indicated schematically by box 208. In some embodiments, monitoring the measured inductance includes monitoring the measured inductance continuously with a control circuit board, e.g. control circuit board 108, having an inductance to digital integrated circuit. Method 200 includes rejecting the note stack if metal is detected or accepting the note stack into the note handling system if no metal is detected, as indicated schematically by box 210. In accordance with some embodiments, rejection and/or accepting the note stack includes indicating an acceptance and/or a rejection status with an audio or visual indicator of the note handling system. The indicator can be displayed/sounded either before, during or after the note stack is physically accepted or rejected (e.g. before it is either accepted into the note recycler or before it is fed back out of the note passage).

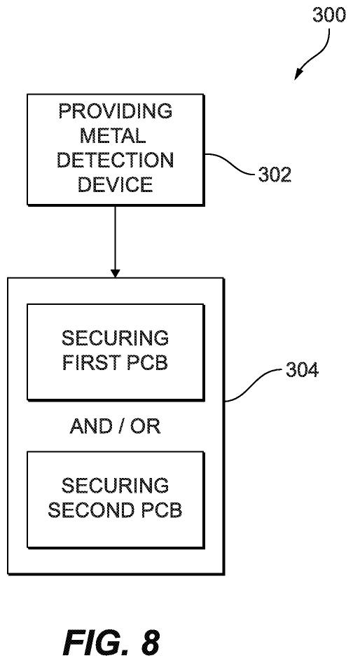

As shown in FIG. 8, a method 300 of retrofitting a note handling system with a metal detection system includes providing a metal detection device, e.g. metal detection device 105, as indicated schematically by box 302. The method includes operatively connecting the metal detection device to a housing, e.g. housing 110, a note passage e.g. note passage 113, or both, for detecting metal foreign objects within the note passage, as indicated schematically by box 304. Operatively connecting the metal detection device includes securing a first PCB, e.g. PCB 106a, on a first side of the note passage and securing a second PCB, e.g. PCB 106b, on a second side of the note passage spaced apart from the first PCB. Securing the first PCB on a first side of the note passage includes securing the first PCB onto an inner surface of an interior wall, e.g. interior wall 114, of the note guide. Securing the second PCB on a second side of the note passage includes securing the second PCB onto an inner surface of the interior wall, wherein the interior wall is between the note passage and the second PCB.

The methods and systems of the present disclosure, as described above and shown in the drawings, provide for improve metal detection compared to convention techniques. While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A metal detection device for detecting metal within notes being placed into a note recycler and handling machine comprising:
a note guide having a note passage, the note passage having a first side and a second side;
a first printed circuit board (PCB) disposed within the first side of the note passage of the note guide, the first PCB including:
a substrate; and
a planar metallic coil deposited on the substrate; and
a second PCB disposed within the second side of the note passage of the note guide, the second PCB including:
a substrate; and
a planar metallic coil deposited on the substrate.

2. The metal detection device of claim 1, wherein the first PCB and the second PCB are parallel to one another.

3. The metal detection device of claim 1, wherein the metallic coil of the first PCB and the metallic coil of the second PCB face one another.

4. The metal detection device of claim 1, wherein at least one of the metallic coils is a rectangular shaped coil.

5. The metal detection device of claim 1, wherein at least one of the metallic coils includes 15 turns.

6. The metal detection device of claim 1, wherein at least one of the metallic coils is formed by a metallic trace arranged in a series of inwardly winding loops, wherein adjacent loops of the metallic coil are spaced apart from one another by 0.008 inches.

7. The metal detection device of claim 6, wherein the metallic trace is 0.010 inches wide.

8. The metal detection device of claim 1, wherein at least one of the first PCB or the second PCB is 0.625 inches wide and 7.2 inches long.

9. The metal detection device of claim 1, wherein the first PCB is spaced apart from the second PCB by a distance that is twice as long as a width of one of the metallic coils.

10. The metal detection device of claim 1, wherein the first PCB and the second PCB each include at least one respective connection point for electrically connecting a circuit to one or both of the metallic coils to monitor inductance of one or both of the metallic coils.

11. A note handling system comprising:
a housing;
a note passage from an exterior of the housing to an interior of the housing; and
a metal detection device operatively connected to at least one of the housing or the note passage for detecting metal foreign objects within the note passage.

12. The system of claim 11, further comprising a note guide within a wall of the housing, wherein the note passage is defined through the note guide.

13. The system of claim 12, wherein the note guide includes an interior wall that defines the note passage.

14. The system of claim 11, further comprising a circuit board within the housing operatively connected to the metal detection device.

15. The system of claim 11, further comprising a note recycler within the housing to receive notes from the note passage.

16. The system of claim 11, wherein the metal detection device includes:
a first printed circuit board (PCB) on a first side of the note passage including:
a substrate; and
a planar metallic coil deposited on the substrate; and
a second PCB spaced apart from the first PCB on a second side of the note passage, the second PCB including:
a substrate; and
a planar metallic coil deposited on the substrate.

17. The system of claim 16, further comprising a note guide within a wall of the housing, wherein the note passage is defined through the note guide, wherein the note guide includes an interior wall that defines the note passage, wherein the interior wall is positioned between the first and second PCB and the note passage.

18. A method for detecting metal in a note handling system using a note handling system as recited in claim 11, the method comprising:
receiving a note stack within the note passage of a note handling system as recited in claim 11; and
detecting metal in the note stack with the metal detection device.

19. The method as recited in claim 18, wherein detecting metal in the note stack with the metal detection device includes applying a current to at least one metallic coil of the metal detection device thereby generating an electro-magnetic field, and monitoring a measured inductance of the at least one metallic coil to determine if metal is detected.

20. The method as recited in claim 19, wherein monitoring the measured inductance includes monitoring the measured inductance continuously with a control circuit board having an inductance to digital integrated circuit.

21. The method as recited in claim 18, further comprising rejecting the note stack if metal is detected.

22. The method as recited in claim 18, further comprising accepting the note stack into the note handling system if no metal is detected.

23. A method of retrofitting a note handling system with a metal detection system, the method comprising:
providing a metal detection device; and
operatively connecting the metal detection device to at least one of a housing or a note passage for detecting metal foreign objects within the note passage.

24. The method of claim 23, wherein operatively connecting the metal detection device includes:
securing a first PCB on a first side of the note passage, the first PCB including a substrate, and a planar metallic coil deposited on the substrate; and
securing a second PCB on a second side of the note passage spaced apart from the first PCB, the second PCB including a substrate and a planar metallic coil deposited on the substrate.

25. The method of claim 24, wherein the note passage is defined through a note guide having an interior wall, wherein securing the first PCB on a first side of the note passage includes securing the first PCB onto an inner surface of the interior wall, wherein the interior wall is between the note passage and the first PCB.

26. The method of claim 24, wherein the note passage is defined through a note guide having an interior wall, wherein securing the second PCB on a second side of the note passage includes securing the second PCB onto an inner surface of the interior wall, wherein the interior wall is between the note passage and the second PCB.
